(19) United States
(12) Patent Application Publication
(10) Pub. No.: US 2025/0225302 A1
(43) Pub. Date: Jul. 10, 2025

(54) Integrated Circuit Design Verification with Object Model

(71) Applicant: SiFive, Inc., San Mateo, CA (US)

(72) Inventors: Jacob Chang, San Jose, CA (US); Henry Cook, Berkeley, CA (US); Sandeep Rajendran, San Mateo, CA (US)

(21) Appl. No.: 18/408,556

(22) Filed: Jan. 9, 2024

(51) Int. Cl. G06F 30/367

(52) U.S. Cl. CPC G06F 30/367

(57) ABSTRACT

Test verification code generation may be automated. Automating the generation of the test verification code may include generating an integrated circuit design for an integrated circuit that includes the object model and generating the verification code based on the object model. The object model is used by a parser to generate a verification code. The object model may include field values including a protection parameter field and a sequence field. The protection parameter field may include information that identifies node(s) that are associated with an intended protected region in the integrated circuit design and indicates characteristics of an encoding scheme applied in the intended protected region. The sequence field may include information representing a list of signals that can report an error. The verification code may be configured to inject the error during simulation of the integrated circuit design to verify that the system correctly responds to the error.

### TECHNICAL FIELD

This disclosure relates generally to integrated circuit design and, more specifically, to integrated circuit design verification with object model.

### BACKGROUND

Integrated circuits may be designed and tested in a multi-step process that involves multiple specialized engineers performing a variety of different design and verification tasks on an integrated circuit design. A variety of integrated circuit design tool chains may be used by these engineers to handle different parts of the integrated circuit design workflow of using commercial electronic design automation (EDA) tools.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a block diagram of an example of a system for facilitating generation and manufacture of integrated circuits.

FIG. 2 is a block diagram of an example of a system for facilitating generation of integrated circuits.

FIG. 3 is a block diagram of an example of a system for generating a verification code that is used to run a simulation for verification test.

FIG. 4 is a block diagram of an example of a system for protection scheme for detecting occurrence of errors in an intended protected region.

FIG. 5 is a flow chart of a method for generating a test verification code based on an object model in accordance with implementations of this disclosure.

FIG. 6 is a flow chart of a method for generating a test verification code based on an object model and running a verification test in accordance with implementations of this disclosure.

### DETAILED DESCRIPTION

Automated generation of integrated circuit designs permits a configuration of an application specific integrated circuit (ASIC) or a system on a chip (SoC) to be specified in terms of design parameters (or colloquially knobs). A system may then automate the operation of commercial electronic design automation (EDA) tools for design of the integrated circuit using the design parameters.

For example, a system may execute an integrated circuit generator (or simply a generator) to access design parameters and generate an integrated circuit design. In some implementations, the generator may use a hardware description language (HDL) embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate an integrated circuit design. The generator may include module descriptions that specify input(s), output(s), and/or a description(s) of a functional operation of a module (e.g., a processor core, cache, or the like, which may be represented, for example, by a Scala class).

In a process referred to as elaboration, the generator may execute to generate an integrated circuit design based on the design parameters. The integrated circuit design may include instances of module descriptions with connections being made. For example, the generator may execute constructor code to establish instances of Scala classes, with wired connections between them, as an instantiation of an integrated circuit design. In some implementations, the integrated circuit design may be encoded in an intermediate representation (IR) data structure. The IR data structure may be configured for optimization and/or translation by a compiler to produce a register-transfer level (RTL) data structure. For example, the generator may generate the integrated circuit design as a flexible intermediate representation for register-transfer level (FIRRTL) data structure (see, e.g., https://aspire.eecs.berkeley.edu/wp/wp-content/uploads/2017/11/Specification-for-the-FIRRTL-Language-Izraelevitz.pdf). The FIRRTL data structure may be compiled by a FIRRTL compiler to produce an RTL data structure.

In a process referred to as compilation, the elaborated integrated circuit design (e.g., the IR data structure) may be compiled to generate an RTL data structure. For example, compiling the integrated circuit design may comprise executing one or more lowering transformations (e.g., compiler transformations that remove high-level constructs) to transform the integrated circuit design to generate the RTL data structure. The RTL data structure may encode a topology of logic associated with the instances of module descriptions implemented in the integrated circuit design (e.g., logic descriptions of the modules, such as the processor cores, caches, and the like). The RTL data structure may be compatible with EDA tools that may be used for functional verification (e.g., simulation analysis), synthesis (e.g., conversion to a gate-level description), placement and routing (e.g., physical design), and/or manufacturing of an integrated circuit (e.g., a processor, a microcontroller, an ASIC, or an SoC). In some implementations, the RTL data structure may comprise Verilog. For example, the integrated circuit design may be compiled using a FIRRTL compiler to generate Verilog.

During the design process, particularly when using Chisel, creating and running verification tests or error detection tests associated with RTL data structure modules, such as processor cores or caches, is critical. However, the traditional approach to testing logic descriptions involves permitting a simulator to write and/or read signal values on nodes associated with a module. While effective, this technique can be manual and time-consuming, especially when dealing with internal nodes in a design. This problem is further compounded by the fact that the error detection units in the design generator may lack a common interface, requiring engineers to manually generate and/or update verification code for each unique error detection scheme.

A significant portion of a project's resources goes into verification, necessitating productivity gains in this area to match those achieved in other parts of the design process. However, when designs are written in Chisel, there is currently no way to automate the generation of verification code for reuse across different modules or designs. This lack of automation creates inefficiencies and a potential misalignment between the RTL data structure and the actual integrated circuit design produced by the generator.

Accordingly, there is a need for a more efficient testing method for logic descriptions in RTL data structures. More specifically, there is a need for the method that can promote automation of generation, update, and/or reuse of verification code, accommodate different error detection schemes without requiring manual intervention, and maintain synchronization between the design and simulation processes.

Described herein are techniques which permit testing of logic descriptions and/or verification code in an RTL data structure (e.g., simulation). An integrated circuit generator and/or a compiler may use Scala or Chisel to generate an integrated circuit design including an object model in a standardized data structure (e.g., a java script object notation (JSON), metadata, etc.), where the object model includes necessary data that can be parsed to generate a verification code. Through use of classes of Chisel or Scala, which can define properties (e.g., data members) and behaviors (e.g., methods) that objects of that class can possess, design codes can be reused through use of libraries that implement an abstract solution, and be instantiated with many different data types. As such, even when the verification code can be written at an abstract level and/or in different data types, the object model (which is generated and/or compiled based on use of classes of Chisel or Scala) may enable reuse of design codes and accommodates different error detection schemes without requiring manual intervention. Moreover, the classes and objects of the Scala or Chisel can be used to create extensive verification code libraries that captures various error detection mechanisms. For example, libraries can be defined based on Chisel classes, where the libraries can serve as a foundation for developing verification codes that relate to various integrated circuit designs.

Accordingly, other integrated circuit designs that utilize such classes and/or objects of Chisel or Scala and utilize such object model may communally use the program, a control interface, and/or the generalized Application Programming Interface (API).

Moreover, the integrated circuit generator and/or a compiler may use Scala or Chisel to generate an integrated circuit design instances of module descriptions. A module description may specify input(s), output(s), and/or a description(s) of a functional operation of a module (e.g., a processor core, cache, or the like, which may be represented, for example, by a Scala class). Instances of module descriptions may include input(s) and/or output(s) (e.g., wires) that may be internal to the integrated circuit design (e.g., as opposed to a system level input(s) and/or output(s) that may be external to the integrated circuit design). The generator (e.g., Chisel) may use an HDL embedded in a general-purpose programming language (e.g., Scala) to generate the integrated circuit design. The integrated circuit design may be encoded in an IR data structure. A control interface, such as an API, may receive a parameter indicating that an input of an instance of a module description should be exposed to a simulator. A compiler (e.g., a FIRRTL compiler) may compile the IR data structure to produce an RTL data structure. The RTL data structure may encode logic descriptions associated with the instances of module descriptions implemented in the integrated circuit design (e.g., Verilog). The parameter may be used to permit a simulator to access a node associated with the input (e.g., to force a signal value to the node) in the RTL data structure.

In some implementations, the control interface may receive a parameter indicating that an output of an instance of a module description should be exposed to a simulator. The parameter may be used to permit a simulator to access a node associated with the output (e.g., to monitor a signal value at the node) in the RTL data structure. In some implementations, a point in the integrated circuit design may be an input and an output (e.g., bi-directional or “I/O”), and the parameter may be used to permit a simulator to access the node associated with the input and the output (e.g., to force a signal value and/or to monitor a signal value at the node) in the RTL data structure. In some implementations, the parameter may be used to generate an annotation for a compiler that is used to compile the integrated circuit design to generate an RTL data structure. For example, the parameter may be used to generate an annotation for a FIRRTL compiler that is used to compile the integrated circuit design to generate Verilog. The annotation may be used to build and/or modify one or more transformations that are used by the compiler. For example, the compiler may use the annotation to configure cross module references, force statements, and/or binding logic (e.g., Verilog forces) to permit access to the one or more nodes by the simulator.

In some implementations, the parameter may be used to generate an annotation for compiler that is used to compile the integrated circuit design to generate an object model. The object model may be used to extract information or data that can be used in generating a verification code. The verification code may involve creating test cases and test suites, which are sets of inputs, conditions, and expected outputs used to validate a functionality of the system (e.g., integrated circuit design) or its components, features, or data transmission. For example, the verification code or other error testing codes may be used by the simulator to simulate error(s), direct, and/or inject the error(s) into the integrated circuit design and check whether or not such circuit design is operating or reacting appropriately to the simulated error(s).

In some implementations, the parameter may be used to generate a configuration file (e.g., instructions) that specifies the node. The configuration file may permit the simulator to force the signal value to the node, and/or monitor a signal value at the node, when simulating the RTL data structure. For example, a simulator that natively supports force statements (e.g., Synopsys VCS®) may use the configuration file to force a signal value to the node, and/or monitor a signal value at the node, when simulating the RTL data structure.

In some implementations, the parameter may be used to configure the RTL data structure to permit the simulator to force the signal value to the node and/or monitor a signal value at the node (e.g., without generating a configuration file). For example, a simulator that does not natively support force statements (e.g., Verilator) may use the RTL data structure, as configured by the compiler, to force a signal value to the node, and/or monitor a signal value at the node, when simulating the RTL data structure. As a result, techniques described herein may permit testing of logic and verification code in an RTL data structure in a way that improves efficiency and/or keeps the design and simulation processes in sync.

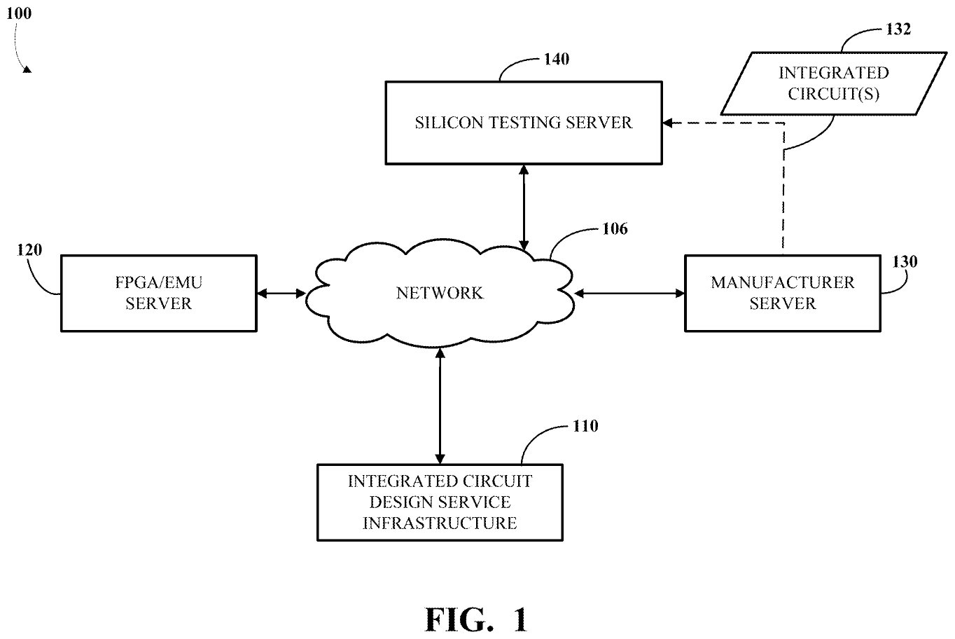

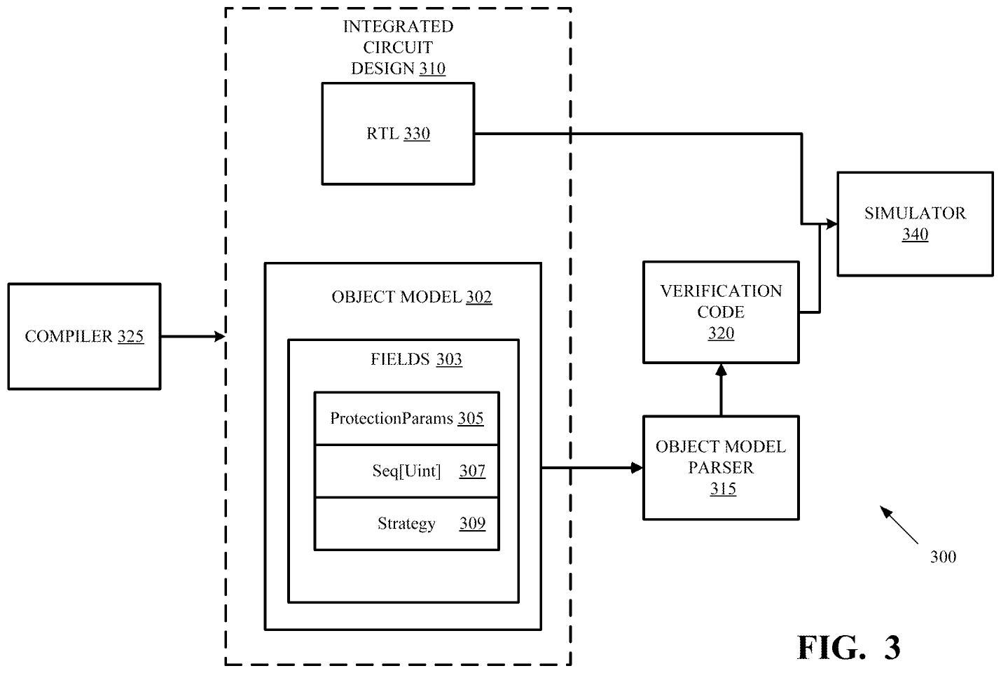

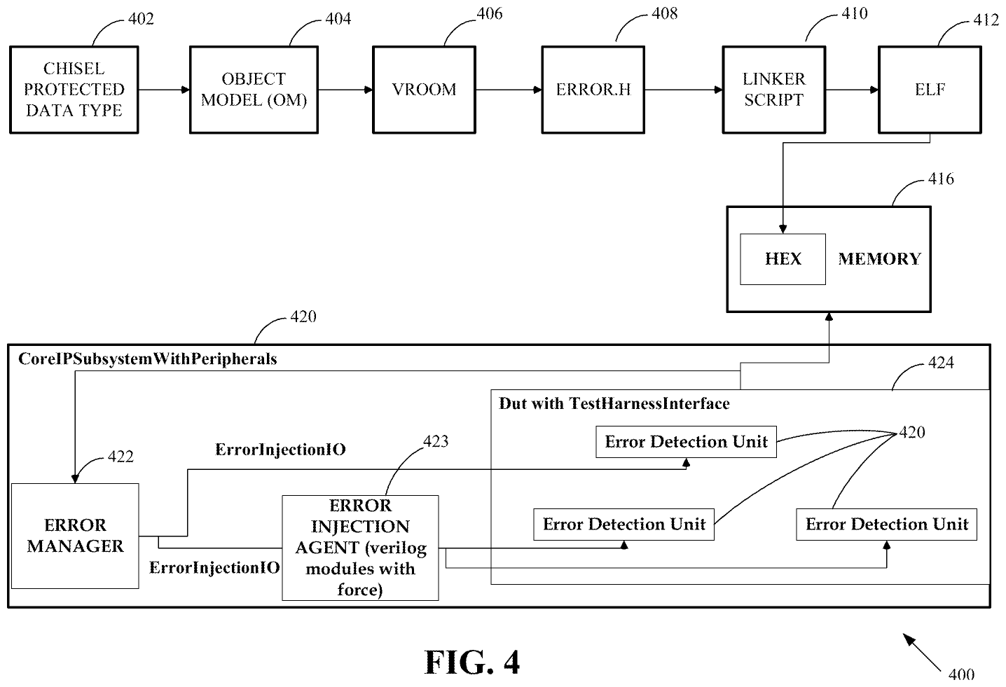

FIG. 1 is a block diagram of an example of a system 100 for generation and manufacture of integrated circuits. The system 100 includes a network 106, an integrated circuit design service infrastructure 110 (e.g., integrated circuit generator), a field programmable gate array (FPGA)/emulator server 120, and a manufacturer server 130. For example, a user may utilize a web client or a scripting API client to command the integrated circuit design service infrastructure 110 to automatically generate an integrated circuit design based on a set of design parameter values selected by the user for one or more template integrated circuit designs. In some implementations, the integrated circuit design service infrastructure 110 may be configured to generate an integrated circuit design like the integrated circuit design 310 shown in FIG. 3, the integrated circuit design 310 shown in FIG. 3, and/or the integrated circuit design shown in FIG. 4.

The integrated circuit design service infrastructure 110 may include a register-transfer level (RTL) service module configured to generate an RTL data structure for the integrated circuit based on a design parameters data structure. For example, the RTL service module may be implemented as Scala code. For example, the RTL service module may be implemented using Chisel. For example, the RTL service module may be implemented using flexible intermediate representation for register-transfer level (FIRRTL) and/or a FIRRTL compiler (available at https://aspire.eecs.berkeley.edu/wp/wp-content/uploads/2017/11/Specification-for-the-FIRRTL-Language-Izraelevitz.pdf). For example, the RTL service module may be implemented using Diplomacy (available at https://carrv.github.io/2017/papers/cook-diplomacy-carrv2017.pdf). For example, the RTL service module may enable a well-designed chip to be automatically developed from a high-level set of configuration settings using a mix of Diplomacy, Chisel, and FIRRTL. The RTL service module may take the design parameters data structure (e.g., JSON file) as input and output an RTL data structure (e.g., a Verilog file) for the chip.

In some implementations, the integrated circuit design service infrastructure 110 may invoke (e.g., via network communications over the network 106) testing of the resulting design that is performed by the FPGA/emulation server 120 that is running one or more FPGAs or other types of hardware or software emulators. For example, the integrated circuit design service infrastructure 110 may invoke a test using a field programmable gate array, programmed based on a field programmable gate array emulation data structure, to obtain an emulation result. The field programmable gate array may be operating on the FPGA/emulation server 120, which may be a cloud server. Test results may be returned by the FPGA/emulation server 120 to the integrated circuit design service infrastructure 110 and relayed in a useful format to the user (e.g., via a web client or a scripting API client).

The integrated circuit design service infrastructure 110 may also facilitate the manufacture of integrated circuits using the integrated circuit design in a manufacturing facility associated with the manufacturer server 130. In some implementations, a physical design specification (e.g., a graphic data system (GDS) file, such as a GDSII file) based on a physical design data structure for the integrated circuit is transmitted to the manufacturer server 130 to invoke manufacturing of the integrated circuit (e.g., using manufacturing equipment of the associated manufacturer). For example, the manufacturer server 130 may host a foundry tape-out website that is configured to receive physical design specifications (e.g., such as a GDSII file or an open artwork system interchange standard (OASIS) file) to schedule or otherwise facilitate fabrication of integrated circuits. In some implementations, the integrated circuit design service infrastructure 110 supports multi-tenancy to allow multiple integrated circuit designs (e.g., from one or more users) to share fixed costs of manufacturing (e.g., reticle/mask generation, and/or shuttles wafer tests). For example, the integrated circuit design service infrastructure 110 may use a fixed package (e.g., a quasi-standardized packaging) that is defined to reduce fixed costs and facilitate sharing of reticle/mask, wafer test, and other fixed manufacturing costs. For example, the physical design specification may include one or more physical designs from one or more respective physical design data structures in order to facilitate multi-tenancy manufacturing.

In response to the transmission of the physical design specification, the manufacturer associated with the manufacturer server 130 may fabricate and/or test integrated circuits based on the integrated circuit design. For example, the associated manufacturer (e.g., a foundry) may perform optical proximity correction (OPC) and similar post-tape-out/pre-production processing, fabricate the integrated circuit(s) 132, update the integrated circuit design service infrastructure 110 (e.g., via communications with a controller or a web application server) periodically or asynchronously on the status of the manufacturing process, perform appropriate testing (e.g., wafer testing), and send to a packaging house for packaging. A packaging house may receive the finished wafers or dice from the manufacturer and test materials and update the integrated circuit design service infrastructure 110 on the status of the packaging and delivery process periodically or asynchronously. In some implementations, status updates may be relayed to the user when the user checks in using the web interface, and/or the controller might email the user that updates are available.

In some implementations, the resulting integrated circuit(s) 132 (e.g., physical chips) are delivered (e.g., via mail) to a silicon testing service provider associated with a silicon testing server 140. In some implementations, the resulting integrated circuit(s) 132 (e.g., physical chips) are installed in a system controlled by the silicon testing server 140 (e.g., a cloud server), making them quickly accessible to be run and tested remotely using network communications to control the operation of the integrated circuit(s) 132. For example, a login to the silicon testing server 140 controlling a manufactured integrated circuit(s) 132 may be sent to the integrated circuit design service infrastructure 110 and relayed to a user (e.g., via a web client). For example, the integrated circuit design service infrastructure 110 may be used to control testing of one or more integrated circuit(s) 132.

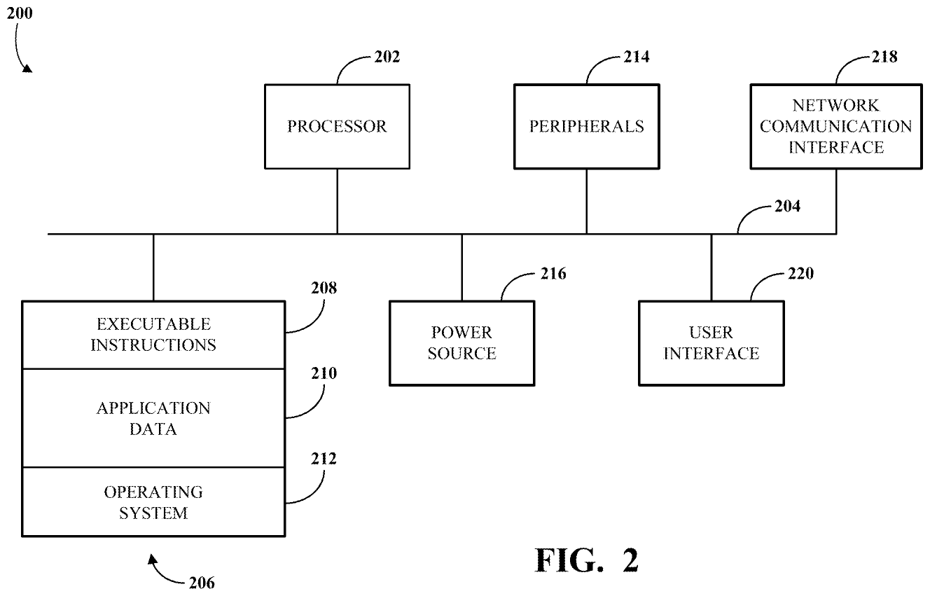

FIG. 2 is a block diagram of an example of a system 200 for facilitating generation of integrated circuits. The system 200 is an example of an internal configuration of a computing device that may be used to implement the integrated circuit design service infrastructure 110. The system 200 can include components or units, such as a processor 202, a bus 204, a memory 206, peripherals 214, a power source 216, a network communication interface 218, a user interface 220, other suitable components, or a combination thereof.

The processor 202 can be a central processing unit (CPU), such as a microprocessor, and can include single or multiple processors having single or multiple processing cores. Alternatively, the processor 202 can include another type of device, or multiple devices, now existing or hereafter developed, capable of manipulating or processing information. For example, the processor 202 can include multiple processors interconnected in any manner, including hardwired or networked, including wirelessly networked. In some implementations, the operations of the processor 202 can be distributed across multiple physical devices or units that can be coupled directly or across a local area or other suitable type of network. In some implementations, the processor 202 can include a cache, or cache memory, for local storage of operating data or instructions.

The memory 206 can include volatile memory, non-volatile memory, or a combination thereof. For example, the memory 206 can include volatile memory, such as one or more dynamic random access memory (DRAM) modules such as double data rate (DDR) synchronous DRAM (SDRAM), and non-volatile memory, such as a disk drive, a solid-state drive, flash memory, Phase-Change Memory (PCM), or any form of non-volatile memory capable of persistent electronic information storage, such as in the absence of an active power supply. The memory 206 can include another type of device, or multiple devices, now existing or hereafter developed, capable of storing data or instructions for processing by the processor 202. The processor 202 can access or manipulate data in the memory 206 via the bus 204. Although shown as a single block in FIG. 2, the memory 206 can be implemented as multiple units. For example, a system 200 can include volatile memory, such as random access memory (RAM), and persistent memory, such as a hard drive or other storage.

The memory 206 can include executable instructions 208, data, such as application data 210, an operating system 212, or a combination thereof, for immediate access by the processor 202. The executable instructions 208 can include, for example, one or more application programs, which can be loaded or copied, in whole or in part, from non-volatile memory to volatile memory to be executed by the processor 202. The executable instructions 208 can be organized into programmable modules or algorithms, functional programs, codes, code segments, or combinations thereof to perform various functions described herein. For example, the executable instructions 208 can include instructions executable by the processor 202 to cause the system 200 to automatically, in response to a command, generate an integrated circuit design and associated test results based on a design parameters data structure. The application data 210 can include, for example, user files, database catalogs or dictionaries, configuration information or functional programs, such as a web browser, a web server, a database server, or a combination thereof. The operating system 212 can be, for example, Microsoft Windows®, macOS®, or Linux®; an operating system for a small device, such as a smartphone or tablet device; or an operating system for a large device, such as a mainframe computer. The memory 206 can comprise one or more devices and can utilize one or more types of storage, such as solid-state or magnetic storage.

The peripherals 214 can be coupled to the processor 202 via the bus 204. The peripherals 214 can be sensors or detectors, or devices containing any number of sensors or detectors, which can monitor the system 200 itself or the environment around the system 200. For example, a system 200 can contain a temperature sensor for measuring temperatures of components of the system 200, such as the processor 202. Other sensors or detectors can be used with the system 200, as can be contemplated. In some implementations, the power source 216 can be a battery, and the system 200 can operate independently of an external power distribution system. Any of the components of the system 200, such as the peripherals 214 or the power source 216, can communicate with the processor 202 via the bus 204.

The network communication interface 218 can also be coupled to the processor 202 via the bus 204. In some implementations, the network communication interface 218 can comprise one or more transceivers. The network communication interface 218 can, for example, provide a connection or link to a network, such as the network 106 shown in FIG. 1, via a network interface, which can be a wired network interface, such as Ethernet, or a wireless network interface. For example, the system 200 can communicate with other devices via the network communication interface 218 and the network interface using one or more network protocols, such as Ethernet, transmission control protocol (TCP), Internet protocol (IP), power line communication (PLC), Wi-Fi, infrared, general packet radio service (GPRS), global system for mobile communications (GSM), code division multiple access (CDMA), or other suitable protocols.

A user interface 220 can include a display; a positional input device, such as a mouse, touchpad, touchscreen, or the like; a keyboard; or other suitable human or machine interface devices. The user interface 220 can be coupled to the processor 202 via the bus 204. Other interface devices that permit a user to program or otherwise use the system 200 can be provided in addition to or as an alternative to a display. In some implementations, the user interface 220 can include a display, which can be a liquid crystal display (LCD), a cathode-ray tube (CRT), a light emitting diode (LED) display (e.g., an organic light emitting diode (OLED) display), or other suitable display. In some implementations, a client or server can omit the peripherals 214. The operations of the processor 202 can be distributed across multiple clients or servers, which can be coupled directly or across a local area or other suitable type of network. The memory 206 can be distributed across multiple clients or servers, such as network-based memory or memory in multiple clients or servers performing the operations of clients or servers. Although depicted here as a single bus, the bus 204 can be composed of multiple buses, which can be connected to one another through various bridges, controllers, or adapters.

FIG. 3 is a block diagram of an example of a system 300 for generating a verification code that is used to run a simulation for verification test. The system 300 may include an integrated circuit design 310, an object model parser 315, a verification code 320 that is generated by the object model parser 315, a compiler 325, and/or a simulator 340. An integrated circuit generator or the compiler 325 may be used to generate the integrated circuit design 310 that includes the RTL data structure 330 and the object model 302. For example, the integrated circuit design service infrastructure 110 shown in FIG. 1 may be used to generate the integrated circuit design 310. The generator may use an HDL embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate the integrated circuit design 310. The integrated circuit design 310 may be encoded in an IR data structure (e.g., a FIRRTL data structure).

The integrated circuit design 310 may include instances of module descriptions. A module description may describe a functional operation of a module (e.g., operation of a processor core or a cache). The integrated circuit design 310 may be executed so that it is elaborated (e.g., expanded) to include the instances of the module descriptions. For example, the integrated circuit design 310 may be elaborated to include instances 1 through N of module description 1, and instances 1 through M of module description 2. The module descriptions can be manipulated using functions of a general-purpose programming language (e.g., embedded in Scala). Interfaces to the module descriptions can be encoded in types associated with the general-purpose programming language.

An instance of a module description may be representative of hardware to be implemented in the integrated circuit (e.g., the processor core or the cache). For example, module description 1 may correspond to a processor core, and instances 1 through N of module description 1 may correspond to N instances of the processor core. For example, module description 2 may correspond to a cache, and instances 1 through M of module description 2 may correspond to M instances of the cache. Additionally, one or more instances may be configured to be in communication with one or more other instances. For example, the instances of module description 1 may be connected (e.g., wired) to the instances of module description 2, such via an internal system bus (e.g., internal to the integrated circuit design 310). In some implementations, the internal system bus could be a TileLink bus to be implemented in an ASIC or an SoC (see, e.g., https://sifive.cdn.prismic.io/sifive/7bef6f5c-ed3a-4712-866a-la2e0c6b7b13_tilelink_spec_1.8.1.pdf).

An instance of a module description may include inputs and/or outputs that are internal to the integrated circuit design 310 (e.g., internal inputs and/or outputs). An instance of a module description may also include inputs and/or outputs that are external to the integrated circuit design 310 (e.g., system level inputs and/or outputs).

The integrated circuit design 310 may be compiled by the compiler 325 (e.g., execute the transformations) to generate the RTL data structure 330 and the object model 302. The RTL data structure 330 may encode logic descriptions associated with the instances of module descriptions implemented in the integrated circuit design 310. In some implementations, the compiler 325 may be a FIRRTL compiler that compiles the integrated circuit design 310 to generate the RTL data structure 330 and the object model 302. In some implementations, the RTL data structure 330 may comprise Verilog.

When the integrated circuit design 310 is compiled to generate the RTL data structure 330, inputs and/or outputs that are external to the integrated circuit design 310 may be exposed to the simulator 340 in the RTL data structure 330, while inputs and/or outputs that are internal to the integrated circuit design 310 might not be exposed to the simulator 340. Accordingly, in some implementations, a control interface (e.g., API) may receive one or more parameters indicating that one or more inputs and/or outputs that are internal to the integrated circuit design 310 should be exposed to the simulator 350. This may permit the simulator 340 to force signal values to, and/or monitor signal values at, one or more nodes associated with the one or more inputs and/or outputs. For example, this may permit the simulator 340 to force signal values to, and/or monitor signal values at, one or more nodes that are associated with the intended protected region of the integrated circuit design 310. For example, the control interface may receive the one or more parameters pointing to the inputs and/or outputs in the integrated circuit design 310. For example, the control interface may receive a first parameter pointing to an input of instance 1 of module description 1, indicating that such input should be exposed to the simulator 340 (e.g., for injecting a signal value or logic on a node associated with the input). The input and the node may correspond to a same point in the design. For example, the input of instance 1 of module description 1 may be an input associated with the internal system bus in the integrated circuit design 310. The control interface may also receive a second parameter pointing to an output of instance 1 of module description 1, indicating that such output should be exposed to the simulator 350 (e.g., for detecting a signal value or logic on a node associated with the output). The output and the node may correspond to a same point in the design. For example, the output of instance 1 of module description 1 may be an output associated with the internal system bus in the integrated circuit design 310.

In some implementations, a point in the integrated circuit design 310 may be an input and an output (e.g., bi-directional or I/O). The control interface may receive a parameter indicating that the input and the output should be exposed to the simulator 340 (e.g., for injecting a signal value or logic and/or detecting a signal value or logic on a node associated with the input and the output).

In some implementations, the parameter may be used to generate an annotation for compiler 325 that is used to compile the integrated circuit design 310 to generate an object model 302. The object model 302 may be used to extract information or data that can be used in generating the verification code 320. The verification code 320 may involve creating test cases and test suites, which are sets of inputs, conditions, and expected outputs used to validate a functionality of the system (e.g., integrated circuit design) or its components, features, or data transmission. For example, the verification code 320 or other error testing codes may be used by the simulator 340 to simulate error(s), direct, and/or inject the error(s) into the integrated circuit design 310 and check whether or not such circuit design is operating or reacting appropriately to the simulated error(s).

The control interface may generate, based on the parameter(s) received, one or more compiler annotations for the compiler 325. The annotations may be used to build and/or modify one or more transformations that are executed by the compiler 325, such as to configure cross module references, force statements, and/or binding logic with respect to one or more nodes in the RTL data structure 330 (e.g., associated with the inputs and/or outputs specified by the parameters). This may permit access to the one or more nodes by the simulator 340. This may also permit mapping the one or more nodes to force statements, as opposed to wires in the RTL data structure 330. In some implementations, the annotations may comprise one or more strings in a serialized data format.

The compiler 325 may execute the one or more transformations, based on the annotations, to generate a configuration file (e.g., instructions) that may be used by the simulator 340. The configuration file may permit the simulator 340 to access the one or more nodes (e.g., one or more nodes that are associated with the intended protected region of the integrated circuit design 310) in the RTL data structure 330. For example, the configuration file may include representations of cross module references, force statements, and/or binding logic that permit the simulator 340 to access the one or more nodes when simulating the RTL data structure 330. In some implementations, the configuration file may comprise Verilog. Accordingly, driving logic may be configured in the annotations, based on the one or more parameters specifying internal input(s) and/or output(s) in the integrated circuit design 310, for the compiler 325 to produce driving logic for the simulator to use in connection with nodes in the RTL data structure 330 that are associated with the input(s) and/or output(s).

In some implementations, the control interface may cooperate with the object model parser 315 to execute in the system 300 to generate one or more compiler annotations for the compiler 325.

The integrated circuit design 310 may include the object model 302. The object model 302 may be the metadata, JSON file, or the like, which includes the fields 303. As described above, the object model 302 may be used (e.g., by the object model parser 315) to extract information or data that can be used in generating the verification code 320.

The fields 303 may include at least a protection parameter field 305 and a sequence field 307. The fields 303 may be generated by Scala or Chisel such that the object model 302 may be generated, used, or applied in different integrated circuit designs that use the Scala, Chisel, or the compiler (that utilizes Scala or Chisel) or the generator (that utilizes Scala or Chisel).

The protection parameter field 305 may include information and/or values that identify one or more nodes that are associated with an intended protected region of the integrated circuit design 310 and indicate characteristics of an encoding scheme applied in the intended protected region. Moreover, the intended protected region may include any other integrated circuit designs that utilize Scala or Chisel. For example, the one or more nodes associated with the intended protected region or the intended protected region may include information based on instances of the module descriptions (e.g., instances that are internal or external to the integrated circuit design 310). The encoding scheme may be an error detection and correction (EDAC) scheme or a protection scheme for testing the intended protected region through a verification code (such as the verification code 320) and/or other error testing codes that can be used to simulate environment or a testbench for design under test (DUT). For example, the verification code 320 may be used verify that a system such as the system 300, its component, or feature behaves as expected. For example, the verification code 320 may involve creating test cases and test suites, which are sets of inputs, conditions, and expected outputs used to validate a functionality of the system 300 or its components, features, or data transmission. The verification code 320 of the system 300 may be supplanted with other error testing codes (such as error detection codes which may be used to detect and/or correct errors in a system such as the system 300 or its components, features, or data transmission). Such codes (e.g., verification code, error detection codes, other error testing codes) can be used to provide stimuli (e.g., normal operation, error conditions) or inputs to the intended protected region and check that the outputs of the intended protected region or corresponding design are as expected. In other words, such codes may be used to check if the intended protected region or the corresponding circuit design behaves correctly.

Moreover, the protection parameter field 305, the sequence field 307, and a strategy field 309 may include information and/or values that relate to any of the instance of the module description that is described above.

The sequence field 307 may include information representing a list of signals that can report an error that may be associated with the EDAC scheme or the protection scheme.

Moreover, optionally, the fields 303 may include strategy field 309 that represent a type of the encoding scheme used by an error detection unit that is located within or connected to (or communicating with) the integrated circuit design 310 or the other integrated circuit designs that are associated with the instance of the module description. For example, the system 300 may utilize the error detection unit for verification test purposes, and there may be different types of encoding schemes that can be used by the error detection unit.

When generating the object model 304, the compiler 325 and/or the integrated circuit design 310 may utilize Scala or Chisel such that the object model 302 may be generated, used, or applied in different integrated circuit designs that use the Scala, Chisel, or the compiler (that utilizes Scala or Chisel) or the generator (that utilizes Scala or Chisel). For example, the fields 303 of the object model 304 may be formed by the compiler 325 and/or the integrated circuit design 310 utilizing classes of Chisel or Scala that define properties (E.g., data members) and behaviors (e.g., methods) that objects of that class can possess. For example, classes can be instantiated to create objects, which can then interact with each other and the rest of the program, the control interface, and/or generalized APIs (e.g., APIs). As a consequence, other integrated circuit designs that utilize such classes and/or objects (e.g., of Chisel or Scala) may communally use the program, the control interface, and/or the generalized APIs. For example, by having the other integrated circuit designs (that utilizes Scala or Chisel) to utilize the object model 302, the other integrated circuit designs may use the same program, same control interface, and/or same generalized APIs. For example, in context of error or circuit design test with verification code, the fields 303 may include data or information in a generalized format, which enables or guarantees certain access or access functions by the program, the control interface, and/or the generalized APIs.

As such, by having object model 304 generated by the compiler 325 and/or the integrated circuit design 310 through use of Scala or Chisel, in which the object model 304 can be used in generating the verification code 320, different integrated circuit designs that utilize such classes and/or objects of Chisel or Scala can also generate respective object models and respective verification codes without having to rewrite or update respective verification codes for their integrated circuit designs. Moreover, the classes and objects of the Scala or Chisel can be used to create extensive verification code libraries that captures various error detection mechanisms. For example, by using Chisel classes, libraries that serve as a foundation for developing verification codes that relate to various integrated circuit designs. Moreover, in some implementations, these libraries may be utilized as a foundation or API for developing more specific or diverse verification codes.

In some implementations, the object model 302 may take a form of the generalized API. In such scenario, the object model 302 may transmit or communicate the metadata or the JSON file that includes the fields 303 to the object model parser 315.

When the object model 302 itself is the metadata or the JSON file, the integrated circuit design 310 may transmit or communicate the object model 302 with the object model parser 315. Then, the object model parser 315 may parse the metadata or the JSON file and identify one or more nodes that are associated with an intended protected region of the integrated circuit design 310 and/or other integrated circuit designs. Moreover, the object model parser 315 may parse the metadata or the JSON file and identify all error detection related data. The error detection related data may include error detection units and error identifiers associated with the error detection units in the integrated circuit design 310 and/or other integrated circuit designs, and error detection related information. Such identified error detection related data (e.g., error detection unit, error identifier, one or more nodes that are associated with the intended protected region, width of the data being protected, instance path(s) where error(s) can be injected, type of encoding scheme, whether detection scheme is correctable or detectable, meaning of signal, etc.) may be used to generate the verification code 320. Moreover, in some implementations, the identified information may be communicated with the compiler 325.

As described above, the verification code 320 may be a type of code that is used by the simulator (such as the simulator 340) to generate a verification test. For example, as initially described, the verification code 320 may involve creating test cases and test suites, which are sets of inputs, conditions, and expected outputs used to validate a functionality of the system 300 or its components, features, or data transmission. For example, the verification code 320 or other error testing codes described above (which may supplant the verification code 320 in the system 300) may be used by the simulator 340 to simulate error(s), direct, and/or inject the error(s) into the integrated circuit design 310 or other integrated circuit designs that utilize Scala or Chisel, and check whether or not such integrated circuit design 310 or the other integrated circuit design(s) are operating or reacting appropriately to the simulated error(s) that are injected into the integrated circuit design 310 or the other integrated circuit design(s). For example, the verification code 320 or other error testing codes described above may be used to check if the system 300 and its components, features, and/or data transmission are reacting in an appropriate way to the stimuli as expected. For example, the verification code 320 or other error testing codes can be used to provide stimuli (e.g., normal operation, error conditions) or inputs to the intended protected region and check that the outputs of the intended protected region or corresponding design are as expected.

The simulator 340, which may be a simulator that natively supports force statements (such as Synopsys VCS), may use the configuration file to access the one or more nodes when simulating the RTL data structure 330 (e.g., when executing test vectors). In other words, the configuration file may implement the cross module references, force statements, and/or binding logic for simulating the RTL data structure 330.

For example, the simulator 340 may use the configuration file to access a first node associated with an input, such as to inject a signal value or logic to the node (e.g., signal forcing). The simulator 340 may also use the configuration file to access a second node associated with an output, such as to detect a signal value or logic on the node (e.g., signal monitoring). Accordingly, the simulator 340 may simulate the RTL data structure 330, using the configuration file, to verify (e.g., test) logic that is internal to the design as desired for functional verification (e.g., verification test, error detection test, logic description associated with an instance of module description). For example, the simulator 340 may simulate the RTL data structure 330, using the configuration file, to test logic associated with, or test error detection or verification associated with the intended protected region of the integrated circuit design 310 and/or other integrated circuit designs. For example, the simulator 340 may simulate the RTL data structure 330, using the configuration file, to test logic associated with, or test error detection or verification associated with one or more nodes of the intended protected region of the integrated circuit design 310 and/or other integrated circuit designs. For example, the simulator 340 may simulate the RTL data structure 330, using the configuration file, to test logic associated with, or test error detection or verification associated with a cache that is internal to the design by forcing a signal value to a first node (e.g., associated with an input of the cache) and by monitoring a signal value on a second node (e.g., associated with an output of the cache). For example, the simulator 340 may simulate the RTL data structure 330, using the Verilog (e.g., Verilog module), to force a signal value and/or to monitor a signal value at one or more nodes of the intended protected region of the integrated circuit design 310 and/or other integrated circuit designs.

FIG. 4 is a block diagram of an example of a system 400 for protection scheme for detecting occurrence of errors in intended protected region. The system 400 may be used in conjunction with the system 300 of the FIG. 3. For example, the system 400 may be used in conjunction with the system 300 to generate and utilize a verification code, and simulate, detect, and report an error. An integrated circuit generator may be used to generate the system 400. For example, the integrated circuit design service infrastructure 110 shown in FIG. 1 may be used to generate the system 400.

Chisel protected data type 402 may be or include information and/or data related to EDAC scheme or protection scheme for testing an intended protected region through a verification code (such as the verification code 320) and/or other error testing codes that can be used to simulate environment or a testbench for design under test (DUT). The Chisel protected data type 402 may include field values such as values of the fields 303 (which include the protection parameter field 305, the sequence field 307, and/or the strategy field 309). The Chisel protected data type 402 may also take a form of a metadata, JSON file, or the like, which includes the field values.

In some implementations, the Chisel protected data type 402 may be written into an object model 404 in Chisel, and the object model 404 may take a form of the metadata, JSON file, or the like.

The object model 404, in the form of the metadata, JSON file, or the like, may be sent to and be parsed by an object model parser (e.g., the object model parser 315). For example, the object model parser may parse the object model 404 and identify all error detection related data. The error detection related data may include [1] one or more nodes that are associated with an intended protected region of the integrated circuit design and/or other integrated circuit designs, [2] error detection units (e.g., error detection units 420) and error identifiers associated with the error detection units in the integrated circuit design and/or other integrated circuit designs, and [3] error detection related information (e.g., width of the data being protected, instance path(s) where error(s) can be injected, type of encoding scheme, whether EDAC or protection scheme is correctable or detectable, meaning of signal, etc.).

Such identified error detection related data may be transformed by a program or software (such as VROOM 406) into a header file (e.g., error.h header file 408 or .svh file). For example, the object model parser may generate the header file. In some implementations, the object model parser may cooperate with a compiler (e.g., the compiler 325) or RTL generated by the compiler (e.g., the RTL data structure 330) to transform such identified error detection related data into the header file. In some implementations, such header file can be accessed by tests (e.g., verification test) running on system.

Such identified error detection related data may be used to generate test verification code(s) (e.g., the verification code 320) or other error testing codes that can be used to simulate environment or a testbench for DUT. For example, the verification code may be used verify that the system (e.g., the system 300), its component, or feature behaves as expected. For example, the verification code may involve creating test cases and test suites, which are sets of inputs, conditions, and expected outputs used to validate a functionality of the system or its components, features, or data transmission. Such codes (e.g., verification code, error detection codes, other error testing codes) can be used to provide stimuli (e.g., normal operation, error conditions) or inputs to the intended protected region and check that the outputs of the intended protected region or corresponding design are as expected. After the header file and/or verification code(s) or the other error testing codes are generated, linker script 410 may combine the header file, the verification code(s) or the other error testing codes, the RTL, and/or object(s) generated by compiler to an executable program. The executable program may be run by a simulator (e.g., the simulator 340) and/or a linker (e.g., ELF 412), which may place or write specific code or data for the protection scheme or EDAC scheme in a memory 416.

For example, consider a verification test written in C for error detection. This test, which is run by the simulator, possesses a list of points in the design where errors can be injected. Each of these points corresponds to an MMIO location in the Error Monitor (EM) that needs to be poked to inject a bug. Furthermore, there can be an error detection register that the verification test needs to read from to verify that the associated error injection has been successfully detected.

Using the information above (e.g., identified error detection related data, verification test example) different verification tests can be generated, or even a generalized test for the entire error detection system. Here's one simple example of how such a test might be created. First, pick an error injection point to test from the list of possibilities. The index of the chosen error injection point corresponds to the error type, bus width, and instance path. The Error Monitor has the necessary code to inject an error at that index. Second. wait and read from the error reporting register that corresponds to the error index. This will confirm whether the error has been successfully detected. Finally, this process of picking an error injection point and verifying error detection can be repeated for multiple times for a robust test.

In some implementations, the specific code or data for the protection scheme or EDAC scheme may be based on the header file, the verification code(s) or the other error testing codes, the RTL, and/or the object(s).

In some implementations, the specific code or data for the protection scheme or EDAC scheme may be the verification code.

In some implementations, the specific code or data for the protection scheme or EDAC scheme may be written into Memory-Mapped Input/Output (MMIO) register of the memory 416. For example, the specific code or data for the protection scheme or EDAC scheme may be written into the MMIO register in hexadecimal (HEX) system, which refers to way memory addresses or values are represented. For example, the MMIO register may be used to facilitate a processor within the integrated circuit or the system to communicate with peripherals or other hardware components of the integrated circuit or the system.

In some implementations, when the specific code or data for the protection scheme or EDAC scheme is written into the MMIO register, an error manager 422 can be activated.

The error manager 422 of a test harness environment, which may be activated and/or run by the executable program or the simulator, runs verification test or error detection test associated with the protection scheme or EDAC scheme.

For example, the error manager 422 may inject an error associated with the protection scheme or EDAC scheme. For example, the error manager may evaluate or monitor if the DUT 424 correctly detects the error injected by the error manager 422. For example, there are two mechanisms for which an error can be injected by the error manager. The first mechanism is if the hardware has built in error injection logic. The error manager 422 can toggle an appropriate signal to inject an error into the DUT 424. The second mechanism uses the error injection agent 423, which contains Verilog module with the appropriate force function. The force injection point is created by the instance path.

After the error is injected, error detection units 420 may detect injected error and indicate when an impactful fault has occurred in its respective protected region or DUT 424. The error detection units 420 can indicate either a correctable or an uncorrectable error has occurred. This error gets reported to an error reporting system. For example, if an impactful fault occurs in the protected region, then the error detection unit 420 protecting that region will indicate that an error has occurred to an error reporting system. If the error reporting system is notified that an error has occurred, then it may notify the system via signals to external devices or generate an interrupt and the interrupt will be taken.

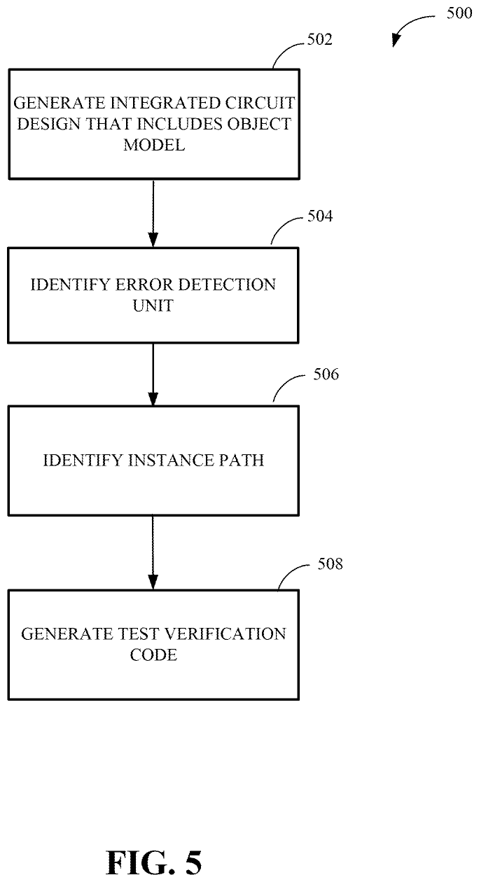

FIG. 5 is a flow chart of a method 500 for generating a test verification code based on an object model in accordance with implementations of this disclosure. The method 500 may be implemented using the system 100 shown in FIG. 1, the system 200 shown in FIG. 2, the system 300 shown in FIG. 3, and the system 400 shown in FIG. 4.

At 502, integrated circuit design that includes an object model (e.g., the object model 302, 404) is generated. For example, an integrated circuit generator (e.g., the integrated circuit generator described initially), may use an HDL embedded in a general-purpose programming language (e.g., Scala) to generate the integrated circuit design, and the integrated circuit design may be encoded in an IR data structure.

Moreover, the integrated circuit design may be compiled by a compiler (e.g., the compiler 325) to generate an RTL data structure and the object model as described above with respect to FIG. 3.

The object model may be the metadata, JSON file, or the like, which includes the field values including at least a protection parameter field and a sequence field. The protection parameter field may include information that identifies one or more nodes that are associated with an intended protected region in the integrated circuit design and indicates characteristics of an encoding scheme applied in the intended protected region. Moreover, the protection parameter field may indicate the characteristics of the encoding scheme based on object classes of a Chisel or Scala language. The sequence filed may include information representing a list of signals that can report an error. In some implementations, the filed values of the object model may further include a strategy field that represents a type of encoding scheme used by a respective error detection unit.

The intended protected region may include one or more nodes that are associated with the intended protected region or may include information based on instances of the module descriptions (e.g., instances that are internal or external to the integrated circuit design). The encoding scheme may be an EDAC scheme or a protection scheme for testing the intended protected region through a verification code (such as the verification code 320) and/or other error testing codes that can be used to simulate environment or a testbench for DUT.

Moreover, when generating the object model, a compiler and/or the integrated circuit design may utilize Scala or Chisel such that the object model may be generated, used, or applied in different integrated circuit designs that use the Scala, Chisel, or the compiler (that utilizes Scala or Chisel) or the generator (that utilizes Scala or Chisel). For example, the fields of the object model may be formed by the compiler and/or the integrated circuit design by utilizing classes of Chisel or Scala that define properties (E.g., data members) and behaviors (e.g., methods) that objects of that class can possess. For example, classes can be instantiated to create objects, which can then interact with each other and the rest of the program, the control interface, and/or generalized APIs (e.g., APIs). As a consequence, other integrated circuit designs that utilize such classes and/or objects (e.g., of Chisel or Scala) may communally use the program, the control interface, and/or the generalized APIs. For example, by having the other integrated circuit designs (that utilizes Scala or Chisel) to utilize the object model, the other integrated circuit designs may use the same program, same control interface, and/or same generalized APIs. For example, in context of error or circuit design test with verification code, the fields may include data or information in a generalized format, which enables or guarantees certain access or access functions by the program, the control interface, and/or the generalized APIs.

At 504, error detection unit(s) is identified, and at 506, instance path(s) is identified. For example, the object model may be used (e.g., by the object model parser 315) to extract error detection related data that includes the error detection unit(s) and instance path(s). As such, through the error detection related data, the error detection unit(s) and the instance path(s) can be identified.

The error detection related data may include data relating to error detection unit(s), error identifier(s) associated with error detection unit(s) in the integrated circuit design and/or other integrated circuit designs, error detection related information, one or more nodes that are associated with the intended protected region, width of the data being protected, instance path(s) where error(s) can be injected, type of encoding scheme, whether detection scheme is correctable or detectable, meaning of signal, etc.

Such error detection related data can be used in generating the verification code. Moreover, in some implementations, the identified information may be communicated with the compiler 325.

At 508, the test verification code is generated. For example, the test verification code is generated at least based on identified error detection unit(s) and identified instance path(s). For example, the test verification code is generated by the object model parser based on the error detection related data.

Moreover, after the test verification code is generated, a simulator (such as the simulator 340) may run the verification test by at least simulating an error, directing, and/or injecting the error into the integrated circuit design, and checking whether or not the circuit design is operating or reacting appropriately to the simulated error, as described with respect to FIGS. 3 and 4. For example, the error can be injected into the instance path(s) and the integrated circuit design or DUT may be monitored to verify whether respective error detection unit is functioning properly, for example, by detecting the error simulated based on the verification code. In some implementations, injecting the error to the instance path(s) can include utilizing an error injection agent that contains Verilog module with a force function, where a force injection point is created by the instance path.

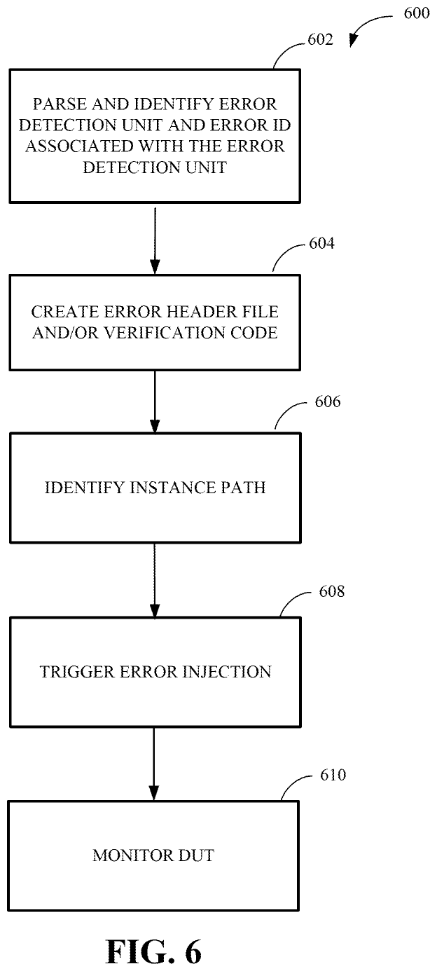

FIG. 6 is a flow chart of a method 600 for generating a test verification code based on an object model and running a verification test in accordance with implementations of this disclosure. The method 600 may be implemented using the system 100 shown in FIG. 1, the system 200 shown in FIG. 2, the system 300 shown in FIG. 3, and the system 400 shown in FIG. 4. Moreover, the method 600 may be viewed in conjunction with, and/or combined with the method 500 in any feasible manner in accordance with implementations of this disclosure.

At 602, error detection related data that includes error detection unit(s) and error identifier(s) (e.g., error id(s)) associated with the error detection units(s) are parsed, and the error detection unit(s) and error id(s) are identified based on the parsed data, as described above with respect to FIGS. 4 and 5. For example, the error detection related data may refer to a data created by parsing an object model (e.g., the object model 302) using an object model parser (e.g., the object model parser 315).

At 604, error header file and/or verification code are created. For example, such parsed error detection related data may be transformed by a program or software (such as the VROOM 406) into a header file (e.g., the error.h header file 408 or .svh file). For example, the object model parser may generate the header file. In some implementations, the object model parser may cooperate with a compiler (e.g., the compiler 325) or RTL generated by the compiler (e.g., the RTL data structure 330) to transform such identified error detection related data into the header file. In some implementations, such header file may itself correspond to verification code or include the verification code, and the header file may be accessed by tests (e.g., verification test) running on system. Otherwise, the verification code may be created in addition to the error header file by the object model parser.

At 606, instance path is identified based on the header file or the verification code. For example, after the header file and/or verification code(s) or the other error testing codes are generated, the header file, the verification code(s) or the other error testing codes, the RTL, and/or object(s) generated by compiler may be combined (e.g., by the linker script 410) to an executable program. The simulator can run the executable program and initiate the verification test.

The executable program may be run (e.g., by the simulator 340, by the linker, etc.) to place or write specific code (e.g., the verification code) for the protection scheme or EDAC scheme in a memory. In some implementations, the specific code or data for the protection scheme or EDAC scheme may be written into MMIO register of the memory. In some implementations, when the specific code or data for the protection scheme or EDAC scheme is written into the MMIO register, an error manager can be activated. The error manager of DUT, which may be activated and/or run by the executable program or the simulator, may run a verification test or error detection test associated with the protection scheme or the EDAC scheme.

At 608, error injection is triggered. For example, the error can be injected into the instance path(s). For example, the error manager may inject an error associated with the protection scheme or EDAC scheme. For example, there may be two mechanisms for which an error can be injected by the error manager. The first mechanism is if the hardware has built in error injection logic. The error manager can toggle an appropriate signal to inject an error into the DUT. The second mechanism uses the error injection agent, which contains Verilog module with the appropriate force function. The force injection point is created by the instance path.

At 610, DUT is monitored. For example, the DUT or the integrated circuit design may be monitored to verify whether respective error detection unit(s) is functioning properly. For example, the error manager may evaluate or monitor if the DUT correctly detects the error injected by the error manager. For example, the error detection unit(s) can indicate either a correctable or an uncorrectable error has occurred. This error gets reported to the error reporting system. For example, if an impactful fault occurs in the protected region, then the error detection unit protecting that region will indicate that an error has occurred to an error reporting system. If the error reporting system is notified that an error has occurred, then it may notify the system via signals to external devices or generate an interrupt.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures.

What is claimed is:

1. A method for generating an automated test verification code, comprising:
generating an integrated circuit design for an integrated circuit, wherein the integrated circuit design includes an object model that is used by a parser to generate a verification code that can be used for the integrated circuit design, wherein:
the object model includes field values including a protection parameter field and a sequence field;
the protection parameter field includes information that identifies one or more nodes that are associated with an intended protected region in the integrated circuit design and indicates characteristics of an encoding scheme applied in the intended protected region,
the sequence field includes information representing a list of signals that can report an error, and
the verification code is configured to inject the error during simulation of the integrated circuit design to verify that the integrated circuit design correctly responds to the error; and
generating the verification code based on the object model.

2. The method of claim 1, wherein:
the object model is generated by using inheritance in a hardware description language used to generate the integrated circuit design; and
the integrated circuit design utilizes classes and objects of a Chisel or a Scala language.

3. The method of claim 1, wherein the protection parameter field indicates the characteristics of the encoding scheme based on object classes of a Chisel or Scala language.

4. The method of claim 3, wherein:
the field values further include a strategy field representing a type of encoding scheme used by a respective error detection unit;
the verification code includes an error injection code; and
the encoding scheme includes one or more instance paths where the error can be injected into.

5. The method of claim 4, further comprising:
identifying the respective error detection unit in one or more different configurations of designs;
identifying an instance path of the one or more instance paths; and
injecting the error simulated based on the verification code to the instance path.

6. The method of claim 5, further comprising:
monitoring the integrated circuit design to verify whether the respective error detection unit is functioning properly, wherein the monitoring includes:
detecting, by the respective error detection unit, the error simulated based on the verification code.

7. The method of claim 5, wherein injecting the error to the instance path comprises:
utilizing an error injection agent that contains Verilog module with a force function, wherein a force injection point is created by the instance path.

8. A non-transitory computer readable medium that includes instructions that, when
executed by a processor, facilitate performance of operations comprising:
generating an integrated circuit design for an integrated circuit, wherein the integrated circuit design includes an object model that is used by a parser to generate a verification code that can be used for the integrated circuit design, wherein:
the object model includes field values including a protection parameter field and a sequence field;
the protection parameter field includes information that identifies one or more nodes that are associated with an intended protected region in the integrated circuit design and indicates characteristics of an encoding scheme applied in the intended protected region,
the sequence field includes information representing a list of signals that can report an error, and
the verification code is configured to inject the error during simulation of the error to the integrated circuit design to verify that the integrated circuit design correctly responds to the error; and
generating the verification code based on the object model.

9. The non-transitory computer readable medium of claim 8, wherein:
the object model is generated by using inheritance in a hardware description language used to generate the integrated circuit design; and
the integrated circuit design utilizes classes and objects of a Chisel or a Scala language.

10. The non-transitory computer readable medium of claim 8, wherein the protection parameter field indicates the characteristics of the encoding scheme based on object classes of a Chisel or Scala language.

11. The non-transitory computer readable medium of claim 10, wherein:
the field values further include a strategy field representing a type of encoding scheme used by a respective error detection unit;
the verification code includes an error injection code; and
the encoding scheme includes one or more instance paths where the error can be injected into.

12. The non-transitory computer readable medium of claim 11, wherein the operations further comprises:
identifying the respective error detection unit in one or more different configurations of designs;
identifying an instance path of the one or more instance paths; and
injecting the error simulated based on the verification code to the instance path.

13. The non-transitory computer readable medium of claim 12, wherein the operations further comprises:
monitoring the integrated circuit design to verify whether the respective error detection unit is functioning properly, wherein the monitoring includes:
detecting, by the respective error detection unit, the error simulated based on the verification code.

14. The non-transitory computer readable medium of claim 12, wherein injecting the error to the instance path comprises:
utilizing an error injection agent that contains Verilog module with a force function, wherein a force injection point is created by the instance path.

15. A computer comprising:
a memory; and
a processor configured to:
generate, based on an object model, a verification code that can be used for an integrated circuit design, wherein:
the object model includes field values including a protection parameter field and a sequence field;
the protection parameter field includes information that identifies one or more nodes that are associated with an intended protected region in the integrated circuit design and indicates characteristics of an encoding scheme applied in the intended protected region;
the sequence field includes information representing a list of signals that can report an error; and
the verification code is configured to inject the error during simulation of the error to the integrated circuit design to verify that the integrated circuit design correctly responds to the error.

16. The computer of claim 15, wherein:
the object model is generated by using inheritance in a hardware description language used to generate the integrated circuit design; and
the integrated circuit design utilizes classes and objects of a Chisel or a Scala language.

17. The computer of claim 15, wherein the protection parameter field indicates the characteristics of the encoding scheme based on object classes of a Chisel or Scala language.

18. The computer of claim 17, wherein:
the field values further include a strategy field representing a type of encoding scheme used by a respective error detection unit;
the verification code includes an error injection code; and
the encoding scheme includes one or more instance paths where the error can be injected into.

19. The computer of claim 18, wherein:
the processor is further configured to:
identify the respective error detection unit and associated identifier of the respective error detection unit;
identify an instance path of the one or more instance paths; and
inject, based on the verification code, the error to the instance path.

20. The computer of claim 19, wherein to inject the error to the instance path comprises to:
utilize an error injection agent that contains Verilog module with a force function, wherein a force injection point is created by the instance path.
